(19) United States
(12) Patent Application Publication
(10) Pub. No.: US 2014/0144675 A1
(43) Pub. Date: May 29, 2014

(54) MULTI-LAYER PRINTED CIRCUIT BOARD AND METHOD FOR MANUFACTURING SAME

(71) Applicant: Zhen Ding Technology Co., Ltd., Tayuan (TW)

(72) Inventor: SHIH-PING HSU, Taoyuan (TW)

(73) Assignee: ZHEN DING TECHNOLOGY CO., LTD., Tayuan (TW)

(21) Appl. No.: 14/084,502

(22) Filed: Nov. 19, 2013

(30) Foreign Application Priority Data
Nov. 28, 2012 (CN) 2012104939772

(51) Int. Cl. H05K 1/02; H05K 3/46

(52) U.S. Cl. CPC H05K 1/0298; H05K 3/4697
USPC 174/251; 156/257

(57) ABSTRACT

An exemplary multi-layer printed circuit board includes a multi-layer substrate with a recess, and a first high density wiring substrate received in the recess. The multi-layer substrate includes a base layer, a first wiring layer arranged on the base layer, first insulating layers, and third wiring layers. The first insulating layers and the third wiring layers are alternately arranged on the first wiring layer, such that there is one first insulating layer sandwiched between each two adjacent wiring layers of the first wiring layer and the third wiring layers. The first high density wiring substrate includes first high density wiring layers and third insulating layers, which are alternately arranged on each other. An outmost first high density wiring layer is exposed outside to define third electrical contact pads corresponding to the first electrical contact pads.

### BACKGROUND

1. Technical Field

The present disclosure generally relates to a method for making a multi-layer printed circuit board, and a multi-layer printed circuit board made by the method.

2. Description of Related Art

To accommodate the development of miniaturized electronic products with multiple functions, multi-layer printed circuit boards are widely used due to their advantageous characteristics such as lightness and high density interconnectability.

In a normal high density multi-layer printed circuit board, a high density area of wiring is usually at a part of the circuit board. In some of these high density multi-layer printed circuit boards, the high density area is at a smaller area of the circuit board. A method for manufacturing the high density multi-layer printed circuit board usually processes a whole circuit area of the circuit board, and so a production efficiency of the high density area is lower than a production efficiency of a low density area of the circuit board. For example, a wire being used in the high density area may be a weak point in the whole circuit board. Accordingly, a production efficiency of the circuit board is lower. In addition, when a method for manufacturing the high density wiring area is used to manufacture the low density wiring area, a cost of the circuit board is higher.

What is needed, therefore, is a method for manufacturing a multi-layer printed circuit board and a multi-layer printed circuit board which overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 shows a circuit substrate according to an exemplary embodiment.

FIG. 2 shows a multi-layer substrate obtained by forming wiring layers and insulating layers at two opposite sides of the circuit substrate of FIG. 1.

FIG. 3 shows a receiving recess formed in each side of the multi-layer substrate of FIG. 2.

FIG. 4 shows a first high density wiring substrate according to the exemplary embodiment.

FIG. 5 shows a plurality of first high density wiring substrates arranged on a tape, each first high density wiring substrate corresponding to the one shown in FIG. 4.

FIG. 6 shows a second high density wiring substrate according to the exemplary embodiment.

FIG. 7 shows a plurality of second high density wiring substrates arranged on a tape, each second high density wiring substrate corresponding to the one shown in FIG. 6.

FIG. 8 shows conductive adhesive layers arranged in each receiving recess of the multi-layer substrate of FIG. 3.

FIG. 9 shows the first and second high density wiring substrates of FIGS. 4 and 6 arranged in the corresponding receiving recesses of the multi-layer substrate of FIG. 8.

FIG. 10 shows an anisotropic conductive film arranged in each receiving recess of the multi-layer substrate of FIG. 3, according to another exemplary embodiment.

FIG. 11 shows conductive solder layers and solder mask structures arranged in each receiving recess of the multi-layer substrate of FIG. 3, according to still another exemplary embodiment.

### DETAILED DESCRIPTION

Embodiments will now be described in detail with reference to the drawings.

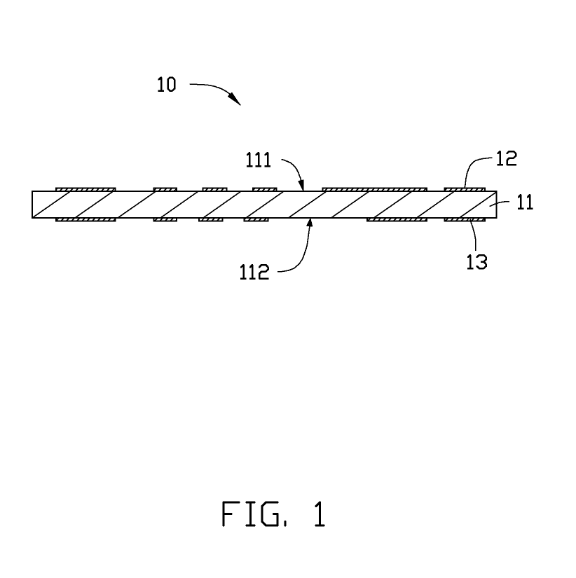

FIGS. 1-11 show that a method for manufacturing a multi-layer printed circuit board (PCB) according to an exemplary embodiment includes the following steps.

FIG. 1 shows step 1, in which a circuit substrate 10 is provided. The circuit substrate 10 includes a base layer 11, a first wiring layer 12, and a second wiring layer 13. The base layer 11 is between the first wiring layer 12 and the second wiring layer 13.

The base layer 11 has a first surface 111, and a second surface 112 facing away from the first surface 111. The first wiring layer 12 is formed on the first surface 111. The second wiring layer 13 is formed on the second surface 112. The first wiring layer 12 and the second wiring layer 13 may be formed by using an image transfer process and an etching process.

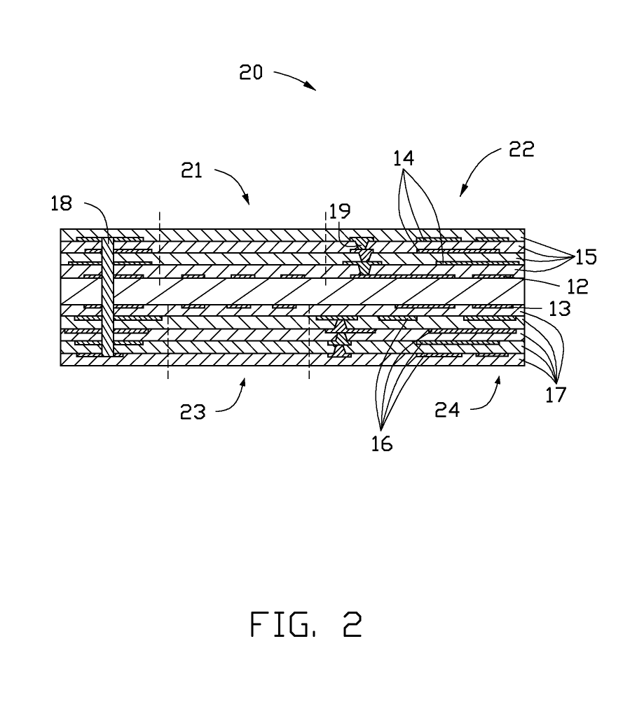

FIG. 2 shows step 2, in which a plurality of first insulating layers 15 and third wiring layers 14 are formed at a side of the first wiring layer 12 using a lamination process. The first insulating layers 15 and the third wiring layers 14 are arranged alternately, such that there is one first insulating layer 15 between two adjacent third wiring layers 14 at the side of the first wiring layer 12. A plurality of second insulating layers 17 and the fourth wiring layers 16 are formed at a side of the second wiring layer 13 using a lamination process. The second insulating layers 17 and the fourth wiring layers 16 are arranged alternately, such that there is one second insulating layer 17 between two adjacent fourth wiring layers 16 at the side of the second wiring layer 13. The first wiring layer 12, the second wiring layer 13, the third wiring layer 14, and the fourth wiring layer 16 are electrically connected to each other by conductive blind vias 18 and 19, thereby obtaining a multi-layer substrate 20

Each of two opposite sides of the base layer 11 of the multi-layer substrate 20 includes a high density wiring area and at least one low density wiring area. In detail, in the illustrated embodiment, a side of the multi-layer substrate 20 adjacent to the first surface 111 includes a first high density wiring area 21 and two first low density wiring areas 22 (only one labeled). A side of the multi-layer substrate 20 adjacent to the second surface 112 includes a second high density wiring area 23 and two second low density wiring areas 24 (only one labeled). In the present embodiment, besides the first wiring layer 12, there is no wire in the first high density wiring area 21. Similarly, besides the second wiring layer 13, there is no wire in the second high density wiring area 23.

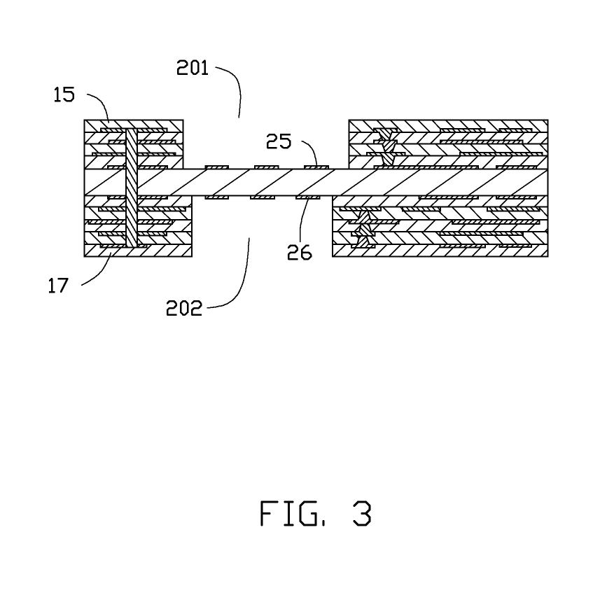

FIG. 3 shows step 3, in which portions of the first insulating layers 15 in the first high density area 21 of the multi-layer substrate 20 are removed from the multi-layer substrate 20 to form a first receiving recess 201. The removing is performed by a laser cutting process or a machine cutting process. Portions of the first wiring layer 12 are exposed to the outside from the first receiving recess 201, and are discontinuous. Such portions define a plurality of first electrical contact pads 25. Portions of the second insulating layers 17 in the second high density area 23 of the multi-layer substrate 20 are removed from the multi-layer substrate 20 to form a second receiving recess 202. The removing is performed by a laser cutting process or a machine cutting process. Portions of the second wiring layer 13 are exposed to the outside from the second receiving recess 202, and are discontinuous. Such portions define a plurality of second electrical contact pads 26.

If there are wires in the first high density wiring area 21 besides the first wiring layer 12, and if there are wires in the second high density wiring area 23 besides the second wiring layer 13, the wires in the first high density wiring area 21 and the second high density wiring area 23 should be respectively removed from the multi-layer substrate 20 along with the portions of the first insulating layers 15 in the first high density area 21 and along with the portions of the second insulating layers 17 in the second high density area 23.

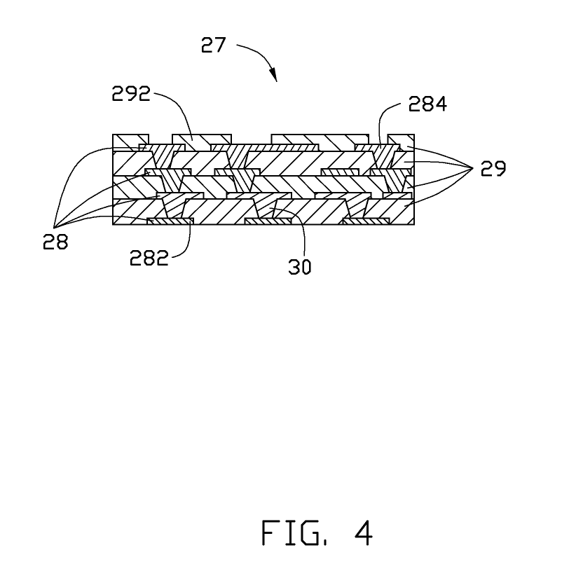

FIG. 4 shows step 4, in which a first high density wiring substrate 27 is formed. The first high density wiring substrate 27 includes a plurality of first high density wiring layers 28 and third insulating layers 29, which are alternately arranged on each other. The first high density wiring layers 28 are electrically connected to each other by first conductive vias 30 in the third insulating layers 29. A bottommost one of the first high density wiring layers 28 is exposed to the outside and is discontinuous, and this first high density wiring layer 28 defines a plurality of third electrical contact pads 282. The number of third electrical contact pads 282 corresponds to the number of the first electrical contact pads 25, and the third electrical contact pads 282 spatially correspond to the first electrical contact pads 25.

A wiring density of each first high density wiring layer 28 is larger than a wiring density of each of the first wiring layer 12 and the second wiring layer 13. In the present embodiment, the first conductive vias 30 are conductive blind vias. A topmost one of the third insulating layers 29 is the outmost top layer of the first high density wiring substrate 27, and is patterned. Such third insulating layer 29 thus defines a first solder mask 292. The first solder mask 292 partially covers the first high density wiring layer 28 that is adjacent to the first solder mask 292. Thereby, portions of that first high density wiring layer 28 adjacent to the first solder mask 292 are exposed, and such portions define a plurality of fourth electrical contact pads 284. The fourth electrical contact pads 284 are configured for having electronic elements mounted thereon. The electronic elements can for example be resistors, capacitors, or chips.

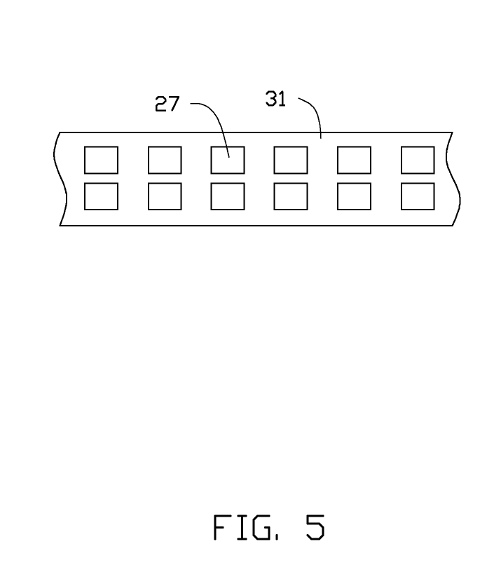

Referring to FIG. 5, a plurality of the first high density wiring substrates 27 are assembled on a first tape 31, to allow the first high density wiring substrates 27 to be easily assembled on a corresponding plurality of the multi-layer substrates 20 by a surface mounting machine.

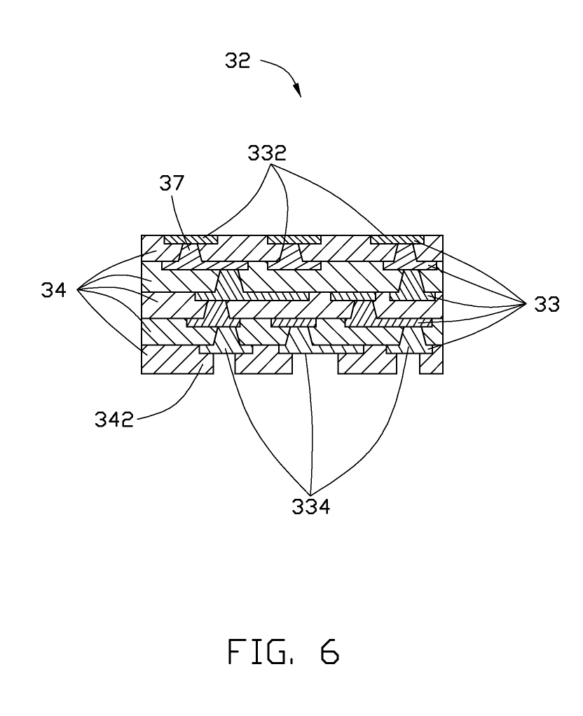

FIG. 6 shows step 5, in which a second high density wiring substrate 32 is formed. The second high density wiring substrate 32 includes a plurality of second high density wiring layers 33 and fourth insulating layers 34, which are alternately arranged on each other. The second high density wiring layers 33 are electrically connected to each other by second conductive vias 37 in the fourth insulating layers 34. A topmost one of the second high density wiring layers 33 is exposed to the outside and is discontinuous, and this second high density wiring layer 33 defines a plurality of fifth electrical contact pads 332. The number of fifth electrical contact pads 332 corresponds to the number of second electrical contact pads 26, and the fifth electrical contact pads 332 spatially correspond to the second electrical contact pads 26.

A wiring density of each second high density wiring layer 33 is larger than a wiring density of each of the first wiring layer 12 and the second wiring layer 13. In the present embodiment, the second conductive vias 37 are conductive blind vias. A bottommost one of the fourth insulating layers 34 is the outmost bottom layer of the second high density wiring substrate 32, and is patterned. Such fourth insulating layer 34 thus defines a second solder mask 342. The second solder mask 342 partially covers the second high density wiring layer 33 that is adjacent to the second solder mask 342. Thereby, portions of the second high density wiring layer 33 adjacent to the second solder mask 342 are exposed, and such portions define a plurality of sixth electrical contact pads 334. The sixth electrical contact pads 334 are configured for having electronic elements mounted thereon. The electronic elements can for example be resistors, capacitors, or chips.

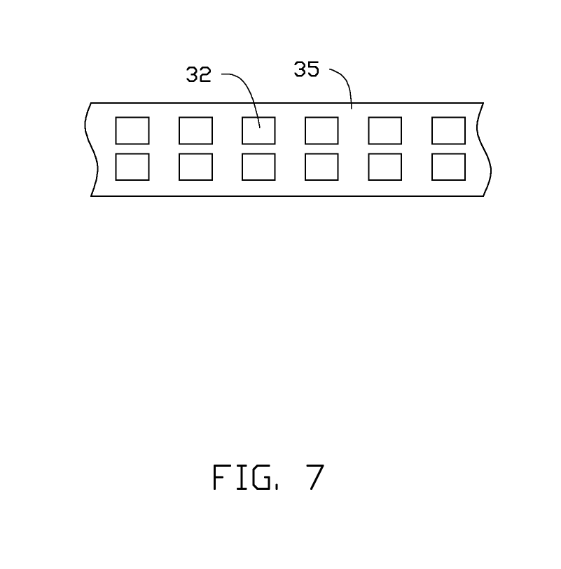

Referring to FIG. 7, a plurality of the second high density wiring substrates 32 are assembled on a second tape 35, to allow the second high density wiring substrates 32 to be easily assembled on the corresponding plurality of the multi-layer substrates 20 by the surface mounting machine.

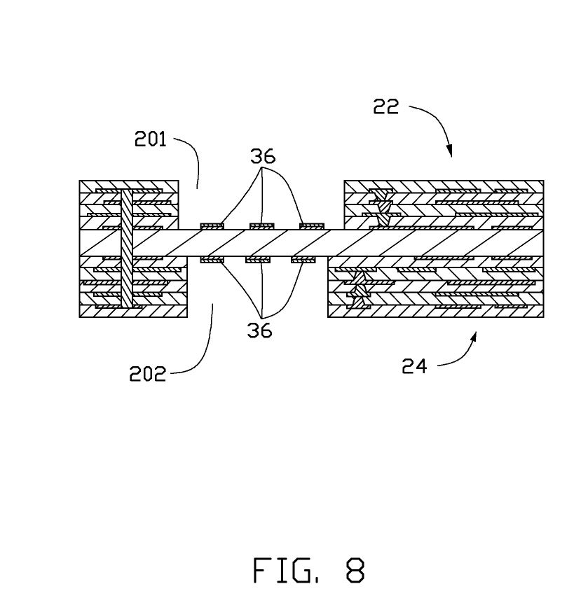

FIG. 8 shows step 6, in which a conductive adhesive layer 36 is formed on each of the first electrical contact pads 25 and each of the second electrical contact pads 26. This is done by printing silver adhesive or copper adhesive on the first and second electrical contact pads 25, 26. The conductive adhesive layer 36 may be silver adhesive, copper adhesive, or conductive solder paste.

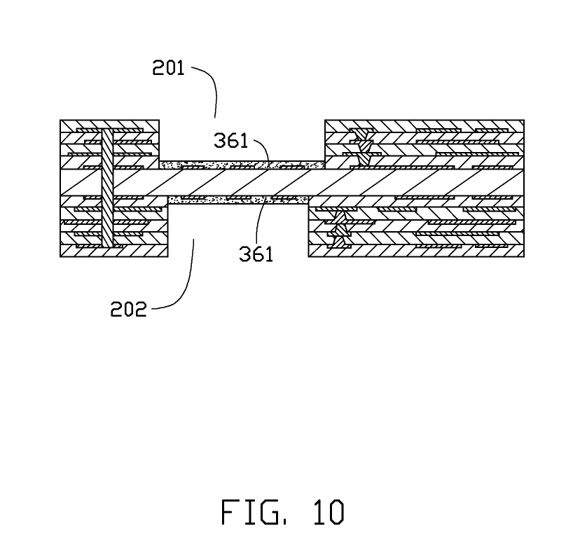

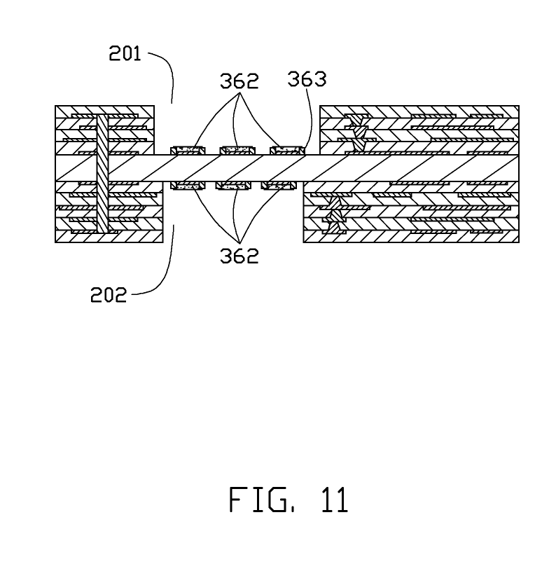

In an alternative embodiment, the conductive adhesive layers 36 may be formed from a pair of anisotropic conductive films 361 (see FIG. 10). In another alternative embodiment, the conductive adhesive layers 36 may be conductive solder layers 362, e.g., layers of tin solder paste (see FIG. 11). In this latter embodiment, before forming the conductive solder layers 362, a solder mask structure 363 may be firstly formed around each of the first electrical contact pads 25 and each of the second electrical contact pads 26. Then the conductive solder layers 362 are formed on outmost surfaces of each of the first electrical contact pads 25 and each of the second electrical contact pads 26.

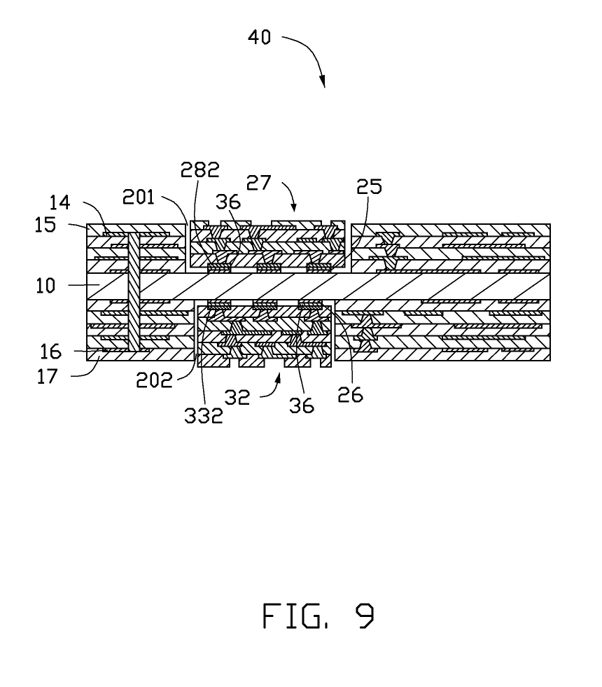

FIG. 9 shows step 7, in which the first high density wiring substrate 27 is fixed in the first receiving recess 201. Each of the third electrical contact pads 282 is electrically connected to the corresponding first electrical contact pad 25 by the corresponding conductive adhesive layer 36. The second high density wiring substrate 32 is fixed in the second receiving recess 202. Each of the fifth electrical contact pads 332 is electrically connected to the corresponding second electrical contact pad 26 by the corresponding conductive adhesive layer 36. Thereby, a multi-layer printed circuit board 40 is formed.

Because the first high density wiring substrates 27 and the second high density wiring substrates 32 are respectively assembled on the first tape 31 and the second tape 35, and because the first tape 31 and the second tape 35 are positioned on a high speed surface mounting machine (not shown), each first high density wiring substrate 27 and each second high density wiring substrate 32 may be respectively assembled on the first electrical contact pads 25 and the second electrical contact pads 26 of the corresponding multi-layer substrate 20 by the high speed surface mounting machine. Alternatively, there may be two high speed surface mounting machines (e.g. a first high speed surface mounting machine and a second high speed surface mounting machine) to assemble the first high density wiring substrates 27 and the second high density wiring substrates 32. In such case, each first high density wiring substrate 27 is assembled on the first electrical contact pads 25 of the corresponding multi-layer substrate 20 by the first high speed surface mounting machine. The multi-layer substrate 20 with the first high density wiring substrate 27 then exits the first high speed surface mounting machine, and is overturned. Then the overturned multi-layer substrate 20 enters the second high speed surface mounting machine, and the second high density wiring substrate 32 is assembled on the second electrical contact pads 26 by the second high speed surface mounting machine.

After assembly of the first high density wiring substrate 27 and the second high density wiring substrate 32 is completed, an outmost surface of each of the first high density wiring substrate 27 and second high density wiring substrate 32 may protrude out of or be parallel and level with a corresponding outmost surface of the multi-layer substrate 20. Alternatively, the outmost surface of each of the first high density wiring substrate 27 and second high density wiring substrate 32 may be recessed inward from the corresponding outmost surface of the multi-layer substrate 20. A gap(s) between a wall(s) of the first receiving recess 201 and the first high density wiring substrate 27 may be filled with resin or may be left empty. A gap between a wall(s) of the second receiving recess 202 and the second high density wiring substrate 32 may be filled with resin or may be left empty.

In actual production, in steps 1 to 3 and steps 6 to 7, the circuit substrate 10 usually includes a plurality of wiring board units. After step 7, there is a cutting step to form a plurality of separated multi-layer printed circuit boards 40. In the present embodiment, it is convenient to describe and show only one circuit substrate 10 and one multi-layer printed circuit board 40.

It is understood that in alternative embodiments, there may be no fourth wiring layers 16, no second insulating layers 17, and no second high density wiring substrate 32. That is, only one side of the circuit substrate 10 has a high density wiring substrate, namely the first high density wiring substrate 27.

As described above, the multi-layer printed circuit board 40 includes a circuit substrate 10, a plurality of third wiring layers 14, a plurality of first insulating layers 15, a plurality of fourth wiring layers 16, a plurality of second insulating layers 17, a first high density wiring substrate 27, and a second high density wiring substrate 32.

The circuit substrate 10 includes a base layer 11, a first wiring layer 12, and a second wiring layer 13. The base layer 11 is between the first wiring layer 12 and the second wiring layer 13. The first insulating layers 15 and the third wiring layers 14 are alternately arranged on a side of the first wiring layer 12 of the circuit substrate 10. The second insulating layers 17 and the fourth wiring layers 16 are alternately arranged on a side of the second wiring layer 13 of the circuit substrate 10. The first receiving recess 201 is formed in the first insulating layers 15. Portions of the first wiring layer 12 are located at the first receiving recess 201, and such portions define a plurality of first electrical contact pads 25. The second receiving recess 202 is formed in the second insulating layers 17. Portions of the second wiring layer 13 are located at the second receiving recess 202, and such portions define a plurality of second electrical contact pads 26.

The first high density wiring substrate 27 includes a plurality of first high density wiring layers 28 and a plurality of third insulating layers 29, which are alternately arranged on each other. The first high density wiring layers 28 are electrically connected to each other by first conductive vias 30 in the third insulating layers 29. A bottommost one of the first high density wiring layers 28 is located at a bottom of the first high density wiring substrate 27, and is discontinuous. Such first high density wiring layer 28 defines a plurality of third electrical contact pads 282. The number of third electrical contact pads 282 corresponds to the number of first electrical contact pads 25, and the third electrical contact pads 282 spatially correspond to the first electrical contact pads 25. A topmost one of the third insulating layers 29 is the outmost top layer of the first high density wiring substrate 27, and is patterned. Such third insulating layer 29 thus defines a first solder mask 292. The first solder mask 292 partially covers the first high density wiring layer 28 that is adjacent to the first solder mask 292. Thereby, portions of the first high density wiring layer 28 adjacent to the first solder mask 292 are exposed, and such portions define a plurality of fourth electrical contact pads 284. The fourth electrical contact pads 284 are configured for having electronic elements mounted thereon. The electronic elements can for example be resistors, capacitors, or chips.

The second high density wiring substrate 32 includes a plurality of second high density wiring layers 33 and a plurality of fourth insulating layers 34, which are alternately arranged on each other. The second high density wiring layers 33 are electrically connected to each other by second conductive vias 37 in the fourth insulating layers 34. A topmost one of the second high density wiring layers 33 is located at a top of the second high density wiring substrate 32, and is discontinuous. Such second high density wiring layer 33 defines a plurality of fifth electrical contact pads 332. The number of fifth electrical contact pads 332 corresponds to the number of second electrical contact pads 26, and the fifth electrical contact pads 332 spatially correspond to the second electrical contact pads 26. A bottommost one of the fourth insulating layers 34 is the outmost bottom layer of the second high density wiring substrate 32, and is patterned. Such fourth insulating layer 34 thus defines a second solder mask 342. The second solder mask 342 partially covers the second high density wiring layer 33 that is adjacent to the second solder mask 342. Thereby, portions of the second high density wiring layer 33 adjacent to the second solder mask 342 are exposed, and such portions define a plurality of sixth electrical contact pads 334. The sixth electrical contact pads 334 are configured for having electronic elements mounted thereon. The electronic elements can for example be resistors, capacitors, or chips.

A wiring density of each of the first high density wiring layers 28 and each of the second high density wiring layers 33 is larger than a wiring density of each of the first wiring layer 12 and the second wiring layer 13. The first high density wiring substrate 27 is fixed in the first receiving recess 201, and each of the third electrical contact pads 282 is electrically connected to the corresponding first electrical contact pad 25 by a corresponding conductive adhesive layer 36. The second high density wiring substrate 32 is fixed in the second receiving recess 202, and each of the fifth electrical contact pads 332 is electrically connected to the corresponding second electrical contact pad 26 by a corresponding conductive adhesive layer 36. A gap(s) between a wall(s) of the first receiving recess 201 and the first high density wiring substrate 27 may be filled with resin or may not be filled with anything. A gap(s) between a wall(s) of the second receiving recess 202 and the second high density wiring substrate 32 may be filled with resin or may not be filled with anything.

In the above-described method for manufacturing the multi-layer printed circuit board 40, the high density wiring areas of the multi-layer printed circuit board 40 (i.e. the first high density wiring substrate 27 and the second high density wiring substrate 32) are fabricated separately from the multi-layer substrate 20. Then these high density wiring areas of the multi-layer printed circuit board 40 are assembled on the multi-layer substrate 20. Accordingly, when either or both of the first high density wiring substrate 27 and the second high density wiring substrate 32 are defective and need to be discarded, this can be done prior to assembly of the first and second high density wiring substrates 27, 32 on the multi-layer substrate 20. Accordingly, a mass production efficiency of the multi-layer printed circuit board 40 is improved, and a cost of the multi-layer printed circuit board 40 is lower.

While certain embodiments have been described and exemplified above, various other embodiments will be apparent from the foregoing to those skilled in the art. The disclosure is not limited to the particular embodiments described and exemplified but is capable of considerable variation and modification without departure from the scope and spirit of the appended claims.

What is claimed is:

1. A method for manufacturing a multi-layer printed circuit board, the method comprising:
providing a multi-layer substrate, the multi-layer substrate comprising a base layer, a first wiring layer arranged on a first side of the base layer, a plurality of first insulating layers, and a plurality of third wiring layers, the first insulating layers and the third wiring layers being alternately arranged on the first wiring layer, such that there is one first insulating layer sandwiched between each two adjacent wiring layers of the first wiring layer and the third wiring layers;
forming a first receiving recess in the combined first insulating layers and third wiring layers, thereby exposing a plurality of portions of the first wiring layer to the outside from the first receiving recess, said portions of the first wiring layer defining a plurality of first electrical contact pads;
providing a first high density wiring substrate, the first high density wiring substrate comprising a plurality of first high density wiring layers and a plurality of third insulating layers which are alternately arranged on each other, an outmost one of the first high density wiring layers being exposed to the outside and defining a plurality of third electrical contact pads corresponding to the first electrical contact pads, and a wiring density of each of the first high density wiring layers being larger than a wiring density of the first wiring layer; and
arranging the first high density wiring substrate in the first receiving recess, and electrically connecting the first electrical contact pads to the corresponding third electrical contact pads to obtain a multi-layer printed circuit board.

2. The method of claim 1, wherein in providing the multi-layer substrate, the multi-layer substrate further comprises a second wiring layer arranged on an opposite second side of the base layer, a plurality of second insulating layers, and a plurality of fourth wiring layers, wherein the second insulating layers and the fourth wiring layers are alternately arranged on the second wiring layer.

3. The method of claim 2, further comprising:
forming a second receiving recess in the combined second insulating layers and fourth wiring layers, thereby exposing a plurality of portions of the second wiring layer to the outside from the second receiving recess, said portions of the second wiring layer defining a plurality of second electrical contact pads;
providing a second high density wiring substrate, the second high density wiring substrate comprising a plurality of second high density wiring layers and fourth insulating layers which are alternately arranged on each other, an outmost one of the second high density wiring layers being exposed to the outside and defining a plurality of fifth electrical contact pads corresponding to the second electrical contact pads, and a wiring density of each of the second high density wiring layers being larger than a wiring density of the second wiring layer; and
arranging the second high density wiring substrate in the second receiving recess, and electrically connecting the second electrical contact pads to the corresponding fifth electrical contact pads to obtain a multi-layer printed circuit board.

4. The method of claim 1, wherein each third electrical contact pad is electrically connected to the corresponding first electrical contact pad by a conductive adhesive layer.

5. The method of claim 4, wherein the conductive adhesive layer is one of silver adhesive, copper adhesive, and conductive solder paste.

6. The method of claim 3, further comprising assembling the first high density wiring substrate on a tape, wherein the first high density wiring substrate is arranged in the first receiving recess by a high speed surface mounting machine.

7. The method of claim 1, wherein in providing the first high density wiring substrate, an outmost one of the third insulating layers is patterned and exposed to the outside and thereby defines a first solder mask, the first solder mask partially covers the first high density wiring layer adjacent to the first solder mask, thereby exposing portions of the first high density wiring layer adjacent to the first solder mask, and the exposed portions of the first high density wiring layer adjacent to the first solder mask define a plurality of fourth electrical contact pads.

8. A multi-layer printed circuit board, comprising:
a multi-layer substrate, the multi-layer substrate comprising a base layer, a first wiring layer arranged on a first side of the base layer, a plurality of first insulating layers, and a plurality of third wiring layers, the first insulating layers and the third wiring layers being alternately arranged on the first wiring layer, such that there is one first insulating layer sandwiched between each two adjacent wiring layers of the first wiring layer and the third wiring layers;
the combined first insulating layers and third wiring layers having a first receiving recess defined therein, a portion of the first wiring layer in the first receiving recess being discontinuous thereby defining a plurality of first electrical contact pads; and
a first high density wiring substrate received in the first receiving recess, the first high density wiring substrate comprising a plurality of first high density wiring layers and a plurality of third insulating layers which are alternately arranged on each other;
an outer one of the first high density wiring layers defining a plurality of third electrical contact pads corresponding to the first electrical contact pads, a wiring density of each of the first high density wiring layers being larger than a wiring density of the first wiring layer, and the first electrical contact pads being electrically connected to the corresponding third electrical contact pads.

9. The multi-layer printed circuit board of claim 8, wherein the multi-layer substrate further comprises a second wiring layer arranged on an opposite second side of the base layer, a plurality of second insulating layers, a plurality of fourth wiring layers, and a second high density wiring substrate, wherein the second insulating layers and the fourth wiring layers are alternately arranged on the second wiring layer, such that there is one second insulating layer sandwiched between each two adjacent wiring layers of the second wiring layer and the fourth wiring layers, the combined second insulating layers and fourth wiring layers have a second receiving recess defined therein, a portion of the second wiring layer in the second receiving recess is discontinuous and thereby defines a plurality of second electrical contact pads, the second high density wiring substrate comprises a plurality of second high density wiring layers and a plurality of fourth insulating layers which are alternately arranged on each other, an outer one of the second high density wiring layers defines a plurality of fifth electrical contact pads corresponding to the second electrical contact pads, a wiring density of each of the second high density wiring layers is larger than a wiring density of the second wiring layer, the second high density wiring substrate is received in the second receiving recess, and the second electrical contact pads are electrically connected to the corresponding fifth electrical contact pads.

10. The multi-layer printed circuit board of claim 8, wherein each third electrical contact pad is electrically connected to the corresponding first electrical contact pad by a conductive adhesive layer.

11. The multi-layer printed circuit board of claim 10, wherein the conductive adhesive layer is one of silver adhesive, copper adhesive, and conductive solder paste.

12. The multi-layer printed circuit board of claim 8, wherein an outmost one of the third insulating layers is patterned and exposed to the outside and thereby defines a first solder mask, the first solder mask partially covers the first high density wiring layer adjacent to the first solder mask, thereby exposing portions of the first high density wiring layer adjacent to the first solder mask, and the exposed portions of the first high density wiring layer adjacent to the first solder mask define a plurality of fourth electrical contact pads.
